(19) United States
(12) Patent Application Publication
(10) Pub. No.: US 2004/0048200 A1
(43) Pub. Date: Mar. 11, 2004

(54) Method for forming fine pattern on substrate by using resist pattern, and resist surface treatment agent

(75) Inventor: Takeo Ishibashi, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 10/453,669

(22) Filed: Jun. 4, 2003

(30) Foreign Application Priority Data
Sep. 11, 2002 (JP) 2002-265429

(51) Int. Cl. G03F 7/16; G03F 7/20; G03F 7/36; G03F 7/40; G03F 7/38; C07G 1/00; C08H 1/00; C09K 3/00; C08G 77/00

(52) U.S. Cl. 430/311; 430/313; 430/327; 430/331; 106/287.1; 106/287.35; 528/10

(57) ABSTRACT

A resist film (1) is deposited on a silicon wafer (W). Next, exposure is performed through an exposure mask (M), following which post-exposure bake is performed. On the silicon wafer (W) after post-exposure bake, a resist surface treatment agent membrane (2) is deposited, where mixing bake is performed. With mixing bake, a resist reinforced portion (R) is formed. Subsequently, an unreacted portion (2a) is removed, and the silicon wafer (W) is dried. The silicon wafer (W) is subjected to plasma dry development for forming a predetermined resist pattern.

### BACKGROUND OF THE INVENTION

1. Field of the Invention

The present invention relates to a method for forming a fine pattern on a substrate in a manufacturing process of a semiconductor device, and materials for use in forming the fine pattern.

2. Description of the Background Art

The following documents present the background art of the present invention: Japanese Patent Application Laid-Open Nos. 11-72922 (hereinafter referred to as document 1); 2-134639; 8-240913; 61-170738; and 2001-52994.

As the integration degree of semiconductor devices becomes higher, finer patterns are required to be formed on semiconductor substrates during manufacturing processes. Such fine patterns on semiconductor substrates are generally formed by photolithography.

Here, an exemplary resist pattern forming method in a conventional photolithography technique will be briefly described referring to sectional views shown in FIGS. 7A through 7D illustrating the flow of steps. First, a resist film 101 is deposited on a silicon wafer W, on which prebake is performed (FIG. 7A). The silicon wafer W with the resist film 101 deposited thereon is radiated with light L from an exposure light source through an exposure mask M, whereby exposure is conducted (FIG. 7B). The silicon wafer W as exposed is subjected to post-exposure bake (FIG. 7C), following which an exposed portion 101b is removed by wet development, and drying is conducted (FIG. 7D). Depending on resists and developing solutions, an unexposed portion 101a may be removed by wet development.

A fine pattern on a semiconductor substrate is formed by selectively etching an underlying thin film using the resist pattern obtained as above described as a mask. Therefore, improved resolution in photolithography, or more specifically, shorter wavelength of an exposure light source is advantageous in forming a finer pattern. Adopting dry etching in an etching step is also advantageous.

On the other hand, with higher integration of semiconductor devices, a complicate device structure is required to be formed on a semiconductor substrate surface. Such complicate device structure causes irregularities of a semiconductor substrate surface, requiring a resist pattern on the semiconductor substrate to be formed thick in a photolithography step. That is, it is necessary to form a resist pattern having a high aspect ratio of film thickness to width. However, it is more difficult to realize a resist material that can provide compatibility between transparency and dry etch resistance as the wavelength of an exposure light source is shortened. This disadvantageously makes it difficult to form a resist pattern having a high aspect ratio.

Various methods have been studied to solve the above-described drawbacks.

For instance, the aforementioned document 1 discloses a top surface imaging resist technique in which a silylated layer having dry etch resistance is formed on a top surface of a resist film, and dry etching is performed using the silylated layer as a mask, thereby transferring a pattern to a region other than the top surface. According to this technique, a resist pattern having a high aspect ratio can be formed using a light source of short wavelength, however, formation of the silylated layer is conducted in a gaseous silylation agent, making it difficult to ensure uniformity in concentration, which causes lack of process stability. Another drawback arises in that a gaseous or liquid silylation agent is difficult to handle.

Another top surface imaging resist technique is commonly known in which silylation is conducted in a liquid silylation agent using hexamethylcyclotrisilazane or the like, which, however, causes similar drawbacks.

Here, an exemplary top surface imaging resist technology will be briefly described referring to sectional views shown in FIGS. 8A through 8E illustrating the flow of steps. First, the resist film 101 is deposited on the silicon wafer W, on which prebake is performed (FIG. 8A). The silicon wafer W with the resist film 101 deposited thereon is radiated with light L from an exposure light source through the exposure mask M, whereby exposure is conducted (FIG. 8B). The silicon wafer W as exposed is subjected to post-exposure bake (FIG. 8C). Subsequently, the top surface of the exposed portion 101b and a gaseous or liquid silylation agent are caused to react with each other to form a resist reinforced portion R (FIG. 8D), following which plasma dry development is performed using the resist reinforced portion R as a mask (FIG. 8E). Depending on resists, the resist reinforced portion R may be formed on the top surface of the unexposed portion 101a.

With the above-described sequential steps, a resist pattern having a high aspect ratio is obtained, however, the use of a gaseous or liquid silylation agent disadvantageously causes lack of process stability. Further, such gaseous or liquid silylation agent is difficult to handle.

### SUMMARY OF THE INVENTION

An object of the present invention is to provide a resist pattern forming method for forming a resist pattern having a high aspect ratio with stability and materials for use in forming such resist pattern.

A first aspect of the present invention is intended for the method for forming a fine pattern on a substrate. The method includes the following steps (a) through (g). The step (a) is to deposit a photoresist film on the substrate. The step (b) is to deposit a resist surface treatment agent membrane having dry etch resistance on the photoresist film. The step (c) is to selectively expose the photoresist film, thereby forming an exposed portion and an unexposed portion on the photoresist film. The step (d) is to provide one of the exposed portion and the unexposed portion with selective reactivity with the resist surface treatment agent membrane. The step (e) is to selectively cause the photoresist film and the resist surface treatment agent membrane to react with each other, thereby forming a mask layer having dry etch resistance. The step (f) is to remove an unreacted portion of the resist surface treatment agent membrane. The step (g) is to perform dry development using the mask layer as a mask.

The deposited resist surface treatment agent membrane is used as a silylation agent membrane, which improves the process stability as well as facilitating handling of materials.

A second aspect of the present invention is intended for the method for forming a fine pattern on a substrate. The method includes the following steps (a) through (i). The step (a) is to form a resin film on the substrate. The step (b) is to deposit a photoresist film on the resin film. The step (c) is to selectively expose the photoresist film, thereby forming an exposed portion and an unexposed portion on the photoresist film. The step (d) is to provide a boundary of one of the exposed portion and the unexposed portion with selective reactivity with a resist surface treatment agent membrane having dry etch resistance. The step (e) is to remove the other of the exposed portion and the unexposed portion. The step (f) is to deposit the resist surface treatment agent membrane on the one of the exposed portion and the unexposed portion and on an uncoated surface of the resin film. The step (g) is to selectively cause the one of the exposed portion and the unexposed portion to react with the resist surface treatment agent membrane, thereby forming a mask layer having dry etch resistance. The step (h) is to remove an unreacted portion of the resist surface treatment agent membrane. The step (i) is to perform dry development of the resin film using the mask layer as a mask.

The deposited resist surface treatment agent membrane is used as a silylation agent membrane, which improves the process stability as well as facilitating handling of materials.

Further, the wiring width of the fine pattern can be made wider than a mask pattern and the isolation width of the resist pattern can be made narrower than the mask pattern, allowing the pattern size to be controlled to exceed the wavelength limit of the light source. In addition, the degree that silylation progresses in a silylated layer does not vary in the depth direction, allowing an excellent resist pattern to be obtained in a shape that rises almost vertically on a silicon wafer.

A third aspect of the present invention is intended for a resist surface treatment agent being selectively caused to react with one of an exposed portion and an unexposed portion of a resist film for use in forming a fine pattern on a substrate, thereby forming a mask layer having dry etch resistance. The resist surface treatment agent contains a dry etch resistive compound having selective reactivity with the one of the exposed portion and the unexposed portion, and a solvent that does not dissolve the resist film obtained by depositing resist on the substrate.

The deposited resist surface treatment agent membrane is used as a silylation agent membrane, which improves the process stability as well as facilitating handling of materials.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A through 1G are sectional views illustrating the flow of steps according to a first preferred embodiment of the present invention;

FIGS. 2A through 2G are sectional views illustrating the flow of steps according to a second preferred embodiment of the present invention;

FIGS. 3A through 3H are sectional views illustrating the flow of steps according to a third preferred embodiment of the present invention;

FIGS. 4A through 4G are sectional views illustrating the flow of steps according to a fourth preferred embodiment of the present invention;

FIGS. 5A through 5G are sectional views illustrating the flow of steps according to a fifth preferred embodiment of the present invention;

FIGS. 6A through 6H are sectional views illustrating the flow of steps according to a sixth preferred embodiment of the present invention;

FIGS. 7A through 7D are sectional views illustrating the flow of steps according to the background art;

FIGS. 8A through 8E are sectional views illustrating the flow of steps according to the background art;

FIG. 9 shows a chemical formula of a copolymer of styrene and hydroxystyrene (vinylphenol);

FIG. 10 shows a chemical formula of a melamine based crosslinking agent;

FIG. 11 shows a chemical formula of triphenylsulfonium trifluoromethylsulfonate;

FIG. 12 shows a chemical formula of an organically modified silicone oil;

FIG. 13 shows a chemical formula of an N-methoxymethylethyleneurea compound;

FIG. 14 shows a chemical formula of a product produced by a crosslinking reaction between the copolymer of styrene and hydroxystyrene (vinylphenol) and the N-methoxymethylethyleneurea compound;

FIG. 15 shows a chemical formula of a product produced by a reaction between the copolymer of styrene and hydroxystyrene (vinylphenol) and the organically modified silicone oil;

FIG. 16 shows a chemical formula of a product produced by a reaction between the organically modified silicone oil and the N-methoxymethylethyleneurea compound;

FIG. 17 shows a chemical formula of a copolymer of styrene and t-butylcarboxynated acrylic acid (t-butylacrylate);

FIG. 18 shows a chemical formula of a product produced by a reaction between the copolymer of styrene and t-butylcarboxynated acrylic acid (t-butylacrylate) and the organically modified silicone oil;

FIG. 19 shows a chemical formula of a polyvinylacetal resin;

FIG. 20 shows a chemical formula of an organically modified silicone oil containing a carbinol group;

FIG. 21 shows a chemical formula of a functional group contained in a titanate coupling agent;

FIG. 22 shows a chemical formula of silane containing a reactive functional group in molecules; and

FIG. 23 shows a chemical formula of an aluminate coupling agent.

### DESCRIPTION OF THE PREFERRED EMBODIMENTS

A fine pattern forming method according to the present invention includes a step of depositing on a semiconductor substrate a resist surface treatment agent membrane that selectively reacts with an exposed portion or unexposed portion in a step of exposing a resist film to form a mask layer having dry etch resistance. The deposited resist film and resist surface treatment agent membrane react with each other by exposure or heat treatment, thereby forming the mask layer. The above resist surface treatment agent membrane can be deposited in either period of “pre-exposure”, “post-exposure and pre-development” or “post-development” in a photolithography step. Further, a resist pattern of either negative type where a mask layer is formed in an exposed portion or positive type where a mask layer is formed in an unexposed portion can be formed. However, the flow of steps is different depending on the period during which a resist surface treatment agent membrane is deposited and the type of resist pattern (positive or negative). In the following preferred embodiments, first to third preferred embodiments are directed to the positive type. The first preferred embodiment corresponds to the “pre-exposure” period, the second preferred embodiment corresponds to the “post-exposure and pre-development” period, and the third preferred embodiment corresponds to the “post-development” period. Fourth to sixth preferred embodiments are directed to the negative type. The fourth preferred embodiment corresponds to the “pre-exposure” period, the fifth preferred embodiment corresponds to the “post-exposure and pre-development” period, and the sixth preferred embodiment corresponds to the “post-development” period.

The first to sixth preferred embodiments will each describe one type of material for resist, a resist surface treatment agent and the like, however, materials are not limited thereto. Other available materials will be described as variants after the first through sixth preferred embodiments.

First Preferred Embodiment

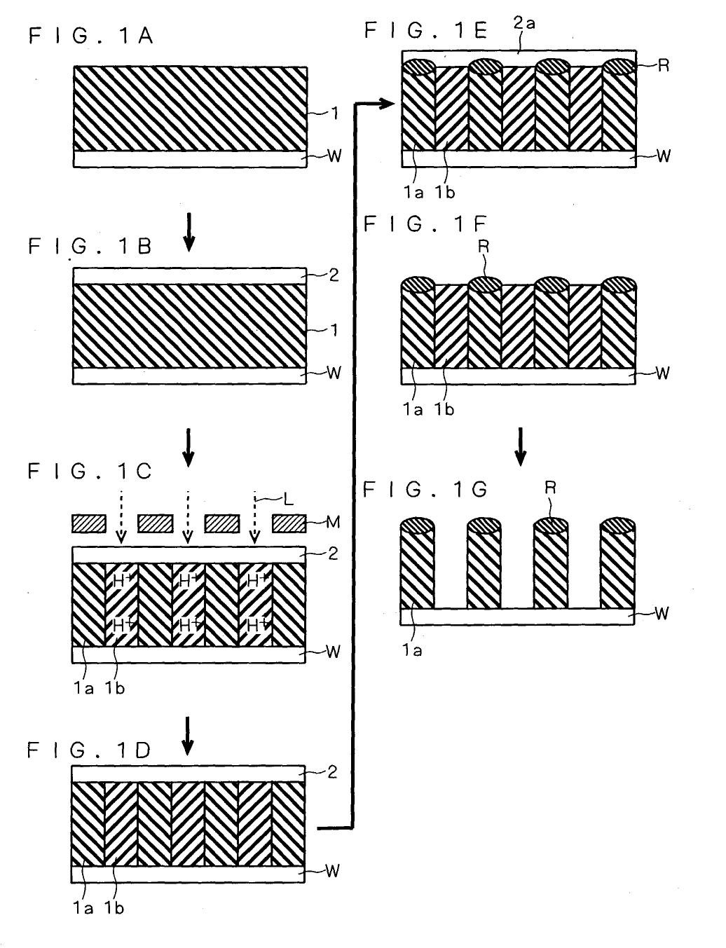

A fine pattern forming method according to the first preferred embodiment will be described referring to sectional views shown in FIGS. 1A through 1G illustrating the flow of steps.

First, a resist film 1 is deposited using a spinner on a silicon wafer W as a substantially circular semiconductor substrate having a notch (or orientation flat) along its arc (FIG. 1A). A predetermined thin film (of metal, insulator or the like) not shown is formed in advance on a surface of the silicon wafer W on which the resist film 1 is to be deposited.

Resist to be used for the resist film 1 is a photoresist of chemically amplified type containing a photo acid generator functioning as a photosensitive agent. More specifically, the resist film 1 is a compound containing the following (1) to (5):

(1) a copolymer of styrene and hydroxystyrene (vinylphenol) as resin (hereinafter briefly referred to as S—co—HS);

(2) a melamine based crosslinking agent;

(3) triphenylsulfonium trifluoromethylsulfonate as a photo acid generator;

(4) a base; and

(5) propyleneglycolmonoethylacetate as a solvent

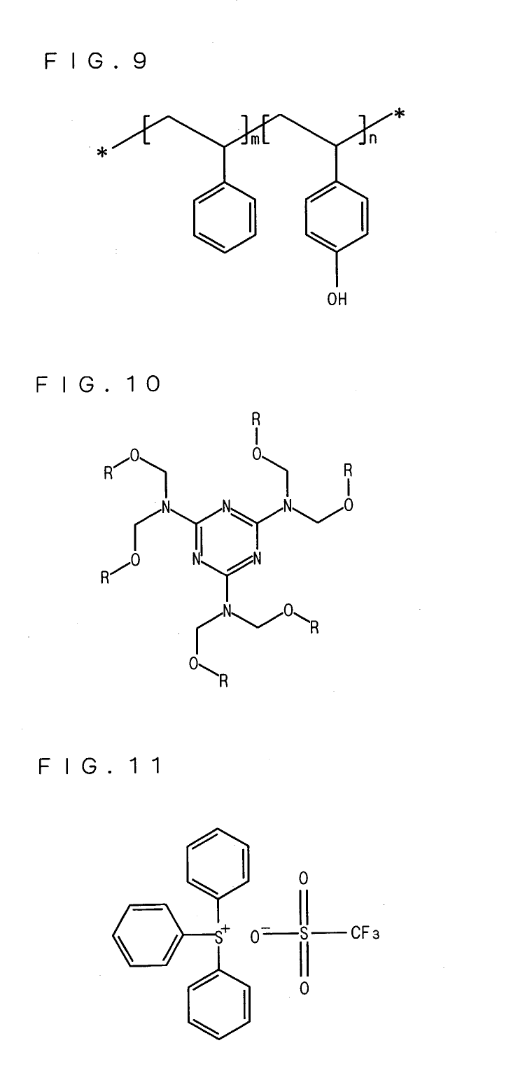

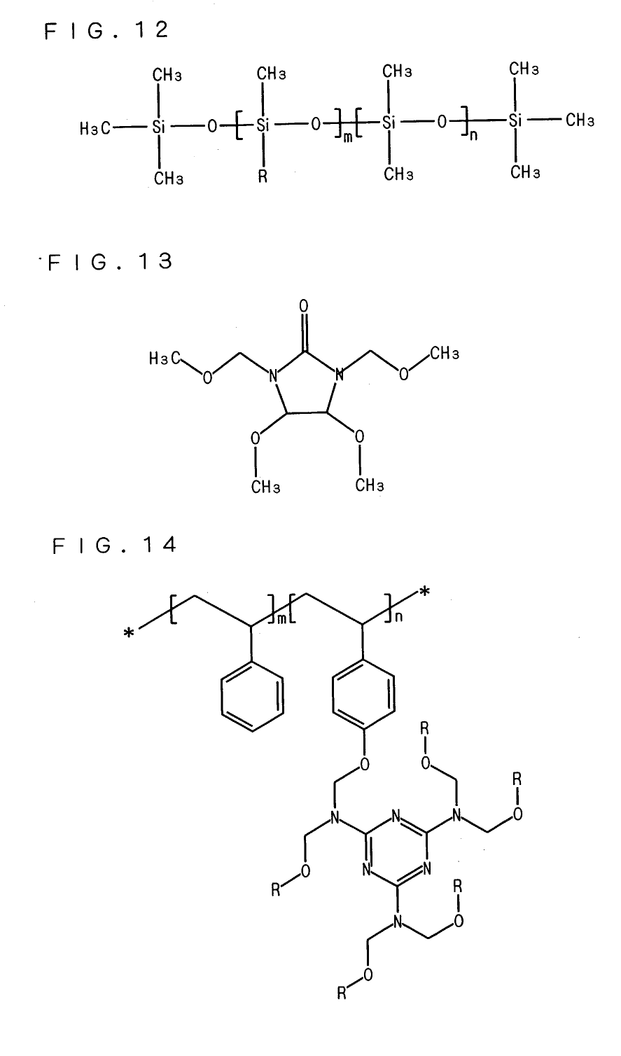

The chemical formulas of S—co—HS, melamine based crosslinking agent and triphenylsulfonium trifluoromethylsulfonate are shown in FIGS. 9 to 11, respectively.

The silicon wafer W on which the resist film 1 is deposited is subjected to prebake at 110° C. for 70 seconds. Prebake causes propyleneglycolmonoethylacetate contained in the resist film 1 to volatilize, making the resist film 1 dense in a film thickness of 0.5 μm.

On the silicon wafer W after prebake, a resist surface treatment agent membrane 2 is deposited on the resist film 1 using a spinner (FIG. 1B). A resist surface treatment agent used for the resist surface treatment agent membrane 2 is obtained by stirring and mixing the following (A) to (C) at room temperature for 2 hours:

(A) 80g of water-soluble organically modified silicone oil (KF354L, Shin-Etsu Chemical Co., Ltd., Chiyoda-ku, Tokyo, Japan) as a Si-containing dry etch resistive compound containing a polyether group;

(B) 20 g of N-methoxymethylethyleneurea compound as a crosslinking compound; and

(C) 800 g of pure water as a solvent

The above mentioned organically modified silicone oil is polysiloxane containing Si in molecules. Part of a side chain of polysiloxane is modified by an organic group R. In the present embodiment, the organic group R is polyether. An end of part of this polyether is a hydrogen atom having reactivity. An exemplary chemical formula of the organically modified silicone oil is shown in FIG. 12.

The aforementioned N-methoxymethylethyleneurea compound is a compound obtained by modifying N-methoxymethylethyleneurea. The chemical formula of the compound is shown in FIG. 13.

The amount of solvent in the resist surface treatment agent used here is controlled so as to have viscosity of such a degree that allows deposition using a spinner. Further, the solvent is selected such that the resist film 1 previously deposited and the resist surface treatment agent membrane 2 are not completely mixed before conducting mixing bake to be described later.

The silicon wafer W after the resist surface treatment agent membrane 2 is deposited thereon is radiated with light L from an exposure light source through an exposure mask M having a predetermined pattern shape, whereby selective exposure is conducted (FIG. 1C). A KrF excimer-laser stepper is used for exposure. Exposure causes triphenylsulfonium trifluoromethylsulfonate to decompose, whereby a proton H⁺ is generated.

The silicon wafer W as exposed is subjected to post-exposure bake at 80 to 200° C. for 30 to 120 seconds (preferably at 120° C. for 70 seconds) (FIG. 1D). With post-exposure bake, S—co—HS contained in the exposed portion 1b produces a crosslinking reaction in the presence of an acid catalyst, whereby phenolic hydroxyl group as a reactive functional group is protected (i.e., the reactivity is lost). An exemplary product by this reaction is shown in FIG. 14.

On the other hand, in the unexposed portion 1a, the phenolic hydroxyl group as a reactive functional group of S—co—HS maintains the reactivity even after post-exposure bake. Thus, post-exposure bake selectively provides the unexposed portion 1a with the reactivity with the resist surface treatment agent membrane 2.

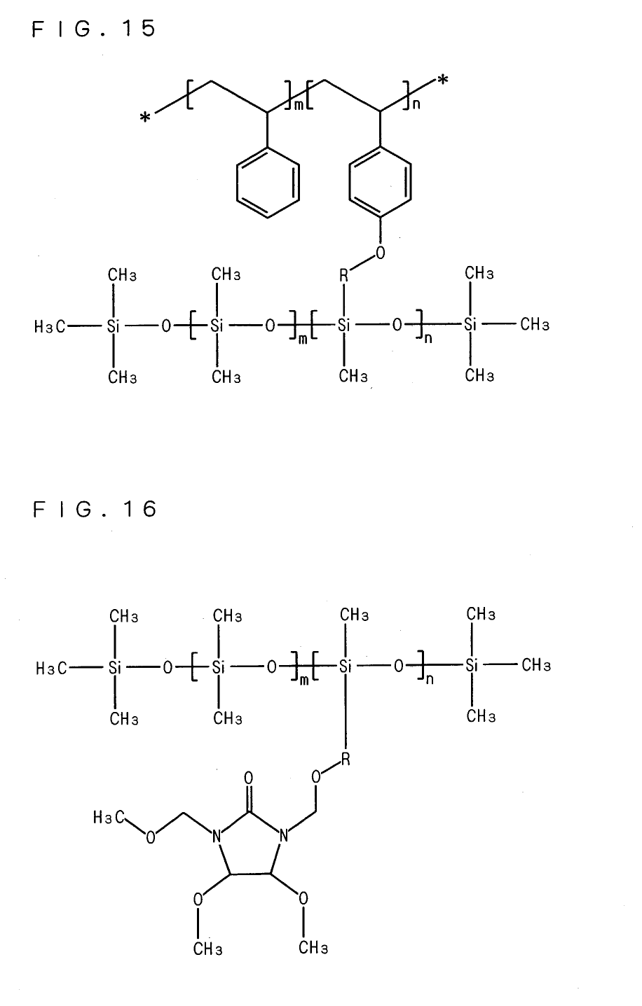

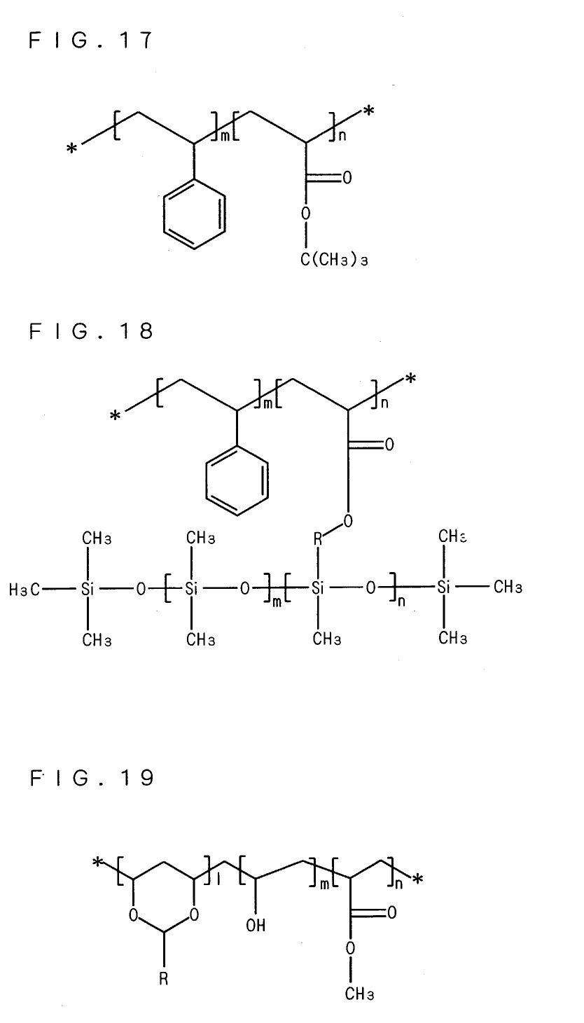

The silicon wafer W after post-exposure bake is subjected to mixing bake at 80 to 200° C. for 30 to 120 seconds (preferably at 120° C. for 90 seconds) (FIG. 1E). With mixing bake, the top surface of the unexposed portion 1a selectively provided with the reactivity reacts with the resist surface treatment agent membrane 2. That is, S—co—HS contained in the unexposed portion 1a reacts with the organically modified silicone oil contained in the resist surface treatment agent membrane 2. At the same time, the reaction between the N-methoxymethylethyleneurea compound and organically modified silicone oil contained in the resist surface treatment agent membrane 2 progresses. Exemplary products by these reactions are respectively shown in FIGS. 15 and 16.

With the progress of these reactions, the resist reinforced portion R that is not removed in a step of developing the resist surface treatment agent to be described later is formed on the top surface of the unexposed portion 1a. The resist reinforced portion R, containing Si in molecules, has an etching rate at the time of dry etching significantly lower than that of other portions. Therefore, the resist reinforced portion R functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the other hand, the reaction between the organically modified silicone oil contained in the resist surface treatment agent membrane 2 and S—co—HS contained in the exposed portion 1b does not progress. Thus, the resist surface treatment agent membrane 2 on the exposed portion 1b is removed in the subsequent step of developing the resist surface treatment agent.

On the silicon wafer W after mixing bake, an unreacted portion 2a of the resist surface treatment agent membrane 2 is developed and removed by a developing solution, following which drying is conducted at 110° C. for 60 seconds (FIG. 1F). In the present embodiment, pure water as a solvent of the resist surface treatment agent is used for a developing solution that only dissolves the unreacted portion 2a and does not dissolve other portions than the unreacted portion 2a.

Next, plasma dry development is performed using the resist reinforced portion R as a mask (FIG. 1G). With plasma dry development, the exposed portion 1b of the resist film 1 is removed leaving the unexposed portion 1a corresponding to a lower layer of the resist reinforced portion R. Thereafter, a thin film is dry etched using the resist pattern formed as described above as a mask.

In the fine pattern forming method according to the present embodiment, the deposited resist surface treatment agent membrane is used as a silylation agent membrane. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved.

Second Preferred Embodiment

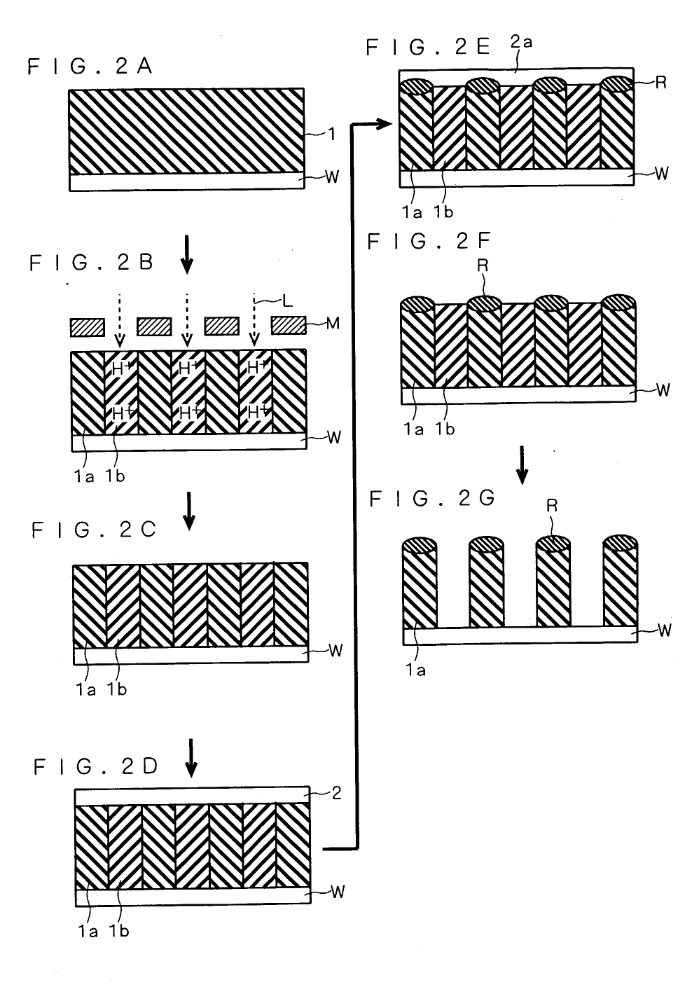

A fine pattern forming method according to the second preferred embodiment will be described referring to sectional views shown in FIGS. 2A through 2G illustrating the flow of steps. The same components described in the first preferred embodiment are assigned the same reference characters in the following description, detailed explanation of which is thus omitted.

The same resist film 1 described in the first preferred embodiment is deposited on the silicon wafer W using a spinner (FIG. 2A).

The silicon wafer W on which the resist film 1 is deposited is subjected to prebake at 110° C. for 70 seconds. Prebake causes propyleneglycolmonoethylacetate contained in the resist film 1 to volatilize, making the resist film 1 dense in a film thickness of 0.5 μm.

The silicon wafer W after prebake is radiated with light L from an exposure light source through the exposure mask M having a predetermined pattern shape, whereby selective exposure is conducted (FIG. 2B). A KrF excimer-laser stepper is used for exposure. Exposure causes triphenylsulfonium trifluoromethylsulfonate to decompose in the exposed portion 1b, whereby a proton H⁺ is generated.

The silicon wafer W as exposed is subjected to post-exposure bake at 80 to 200° C. for 30 to 120 seconds (preferably at 120° C. for 70 seconds) (FIG. 2C). With post-exposure bake, S—co—HS contained in the exposed portion 1b produces a crosslinking reaction in the presence of an acid catalyst, whereby phenolic hydroxyl group as a reactive functional group is protected (i.e., the reactivity is lost).

On the other hand, in the unexposed portion 1a, the phenolic hydroxyl group as a reactive functional group of S—co—HS maintains the reactivity even after post-exposure bake. Thus, post-exposure bake selectively provides the unexposed portion 1a with the reactivity with the resist surface treatment agent membrane 2 to be formed later.

On the silicon wafer W after post-exposure bake, the same resist surface treatment agent membrane 2 described in the first preferred embodiment is deposited on the resist film 1 using a spinner (FIG. 2D).

The silicon wafer W on which the resist surface treatment agent membrane 2 is deposited is subjected to mixing bake at 80 to 200° C. for 30 to 120 seconds (preferably at 120° C. for 90 seconds) (FIG. 2E). With mixing bake, the top surface of the unexposed portion 1a selectively provided with the reactivity reacts with the resist surface treatment agent membrane 2. That is, S—co—HS contained in the unexposed portion 1a reacts with the organically modified silicone oil contained in the resist surface treatment agent membrane 2. At the same time, the reaction between the N-methoxymethylethyleneurea compound and organically modified silicone oil contained in the resist surface treatment agent membrane 2 also progresses.

With the progress of these reactions, the resist reinforced portion R that is not removed in the step of developing the resist surface treatment agent to be described later is formed on the top surface of the unexposed portion 1a. The resist reinforced portion R, containing Si in molecules, has an etching rate at the time of dry etching significantly lower than that of other portions. Therefore, the unexposed portion 1a functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the other hand, the reaction between the organically modified silicone oil contained in the resist surface treatment agent membrane 2 and S—co—HS contained in the exposed portion 1b does not progress. Thus, the unreacted portion 2a of the resist surface treatment agent membrane 2 on the exposed portion 1b is removed in the subsequent step of developing the resist surface treatment agent.

On the silicon wafer W after mixing bake, the unreacted portion 2a of the resist surface treatment agent membrane 2 is developed and removed by the same developing solution (pure water) described in the first preferred embodiment, following which drying is conducted at 110° C. for 60 seconds (FIG. 2F).

Next, plasma dry development is performed using the resist reinforced portion R as a mask (FIG. 2G). With plasma dry development, the exposed portion 1b of the resist film 1 is removed leaving the unexposed portion 1a corresponding to a lower layer of the resist reinforced portion R.

In the fine pattern forming method according to the present embodiment, the deposited resist surface treatment agent membrane 2 is used as a silylation agent membrane as in the first preferred embodiment. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved.

Third Preferred Embodiment

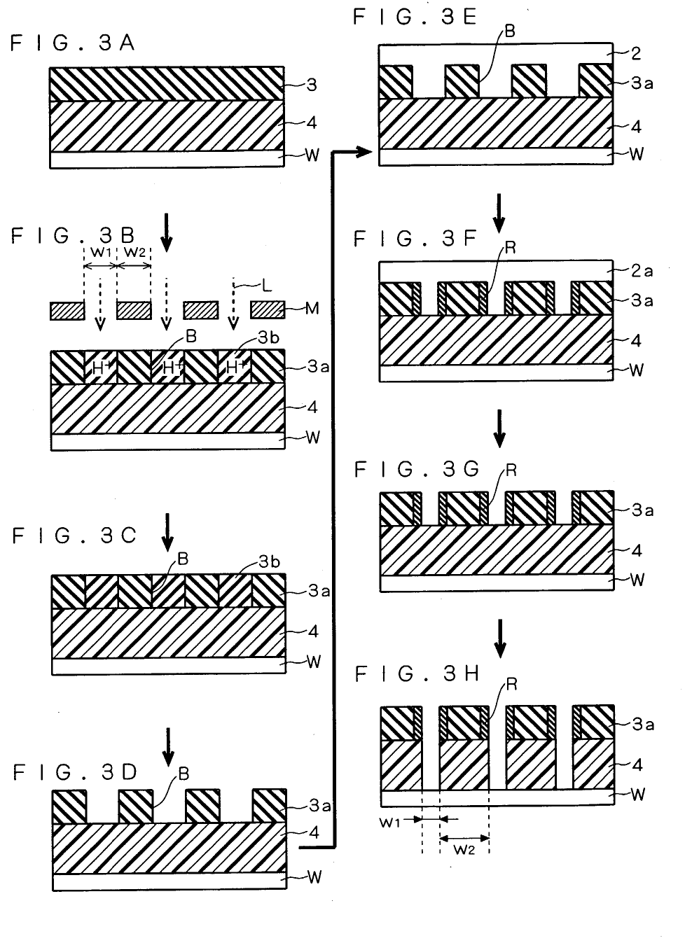

A fine pattern forming method according to the third preferred embodiment will be described referring to sectional views shown in FIGS. 3A through 3H illustrating the flow of steps. The same components described in the first and second preferred embodiments are assigned the same reference characters in the following description, detailed explanation of which is thus omitted.

First, a resin film 4 is deposited on the silicon wafer W using a spinner (FIG. 3A). The resin film 4 is formed of a non-photosensitive resin compound containing S—co—HS, a melamine based crosslinking agent and an acid catalyst. Since the resin film 4 contains the acid catalyst, a crosslinking reaction progresses whether or not exposure is performed in a post-exposure bake process to be described later.

On the silicon wafer W on which the resin film 4 is deposited, a resist film 3 is deposited on the resin film 4 using a spinner. Resist used for the resist film 3 is a chemically amplified photoresist containing a photo acid generator functioning as a photosensitive agent, whose composition differs from that of the resist film 1. More specifically, the resist used for the resist film 3 is a compound containing the following (6) to (9):

(6) a copolymer of styrene and t-butylcarboxynated acrylic acid (t-butylacrylate) as resin (hereinafter briefly referred to as S—co-tBCA; S—co-tBCA may further contain hydroxystyrene as a monomer)

(7) triphenylsulfonium trifluoromethylsulfonate as a photo acid generator

(8) a base

(9) propyleneglycolmonoethylacetate as a solvent

The chemical formula of S—co-tBCA is shown in FIG. 17. S—co-tBCA is a compound in which reactive carboxyl group in the copolymer of styrene and acrylic acid is protected (esterified) by a t-butyl group, causing the reactivity to be lost.

The silicon wafer W on which the resist film 3 is deposited is subjected to prebake at 110° C. for 70 seconds. Prebake causes propyleneglycolmonoethylacetate contained in the resist film 3 to volatilize, making the resist film 3 dense in a film thickness of 0.5 μm.

The silicon wafer W after prebake is radiated with light L from an exposure light source through the exposure mask M having a predetermined pattern shape, whereby selective exposure is conducted (FIG. 3B). A KrF excimer-laser stepper is used for exposure. Exposure causes triphenylsulfonium trifluoromethylsulfonate to decompose, whereby a proton H⁺ is generated.

The silicon wafer W as exposed is subjected to post-exposure bake at 80 to 200° C. for 30 to 120 seconds (preferably at 120° C. for 70 seconds) (FIG. 3C). With post-exposure bake, the t-butyl group of S—co-tBCA contained in an exposed portion 3b is eliminated in the presence of an acid catalyst, whereby S—co-tBCA is deprotected. Therefore, post-exposure bake causes the exposed portion 3b to be alkali-soluble and to have the reactivity with the resist surface treatment agent membrane 2 to be formed later.

On the other hand, S—co-tBCA of an unexposed portion 3a remains protected by the t-butyl group even after post-exposure bake except a boundary region B with respect to the exposed portion 3b. Therefore, the unexposed portion 3a except the boundary region B is alkali-insoluble even after post-exposure, and has no reactivity with the resist surface treatment agent membrane 2.

Further, S—co—HS contained in the resin film 4 produces a crosslinking reaction at post-exposure bake in the presence of an acid catalyst, whereby a phenolic hydroxyl group as a reactive functional group is protected (i.e., the reactivity is lost). Therefore, post-exposure bake causes the resin film 4 to be alkali-insoluble, so that the reactivity with the resist surface treatment agent membrane 2 is lost.

The boundary region B of the unexposed portion 3a with respect to the exposed portion 3b, where deprotection of S—co-tBCA partly progresses, is thus not completely alkali-soluble, but is provided with the reactivity with the resist surface treatment agent membrane 2.

That is, post-exposure bake selectively provides the exposed portion 3b and boundary region B with the reactivity with the resist surface treatment agent membrane 2. However, the exposed portion 3b is removed in the developing step to be described later, which substantially means that the reactivity with the resist surface treatment agent membrane 2 is selectively provided only for the boundary region B.

The silicon wafer W after post-exposure bake is subjected to a developing process for 1 minute with 2.38 wt % aqueous solution of tetramethylammoniumhydroxide (TMAH) as an alkali developing solution. With this developing process, the exposed portion 3b in an alkali-soluble state is removed (FIG. 3D). The silicon wafer W after the developing process is dried at 110° C. for 60 seconds.

On the silicon wafer W as dried, the same resist surface treatment agent membrane 2 described in the first preferred embodiment is deposited using a spinner. Here, the resist surface treatment agent membrane 2 is deposited in such a film thickness that the unexposed portion 3a remaining in an alkali-insoluble state and the boundary region B are completely covered (FIG. 3E).

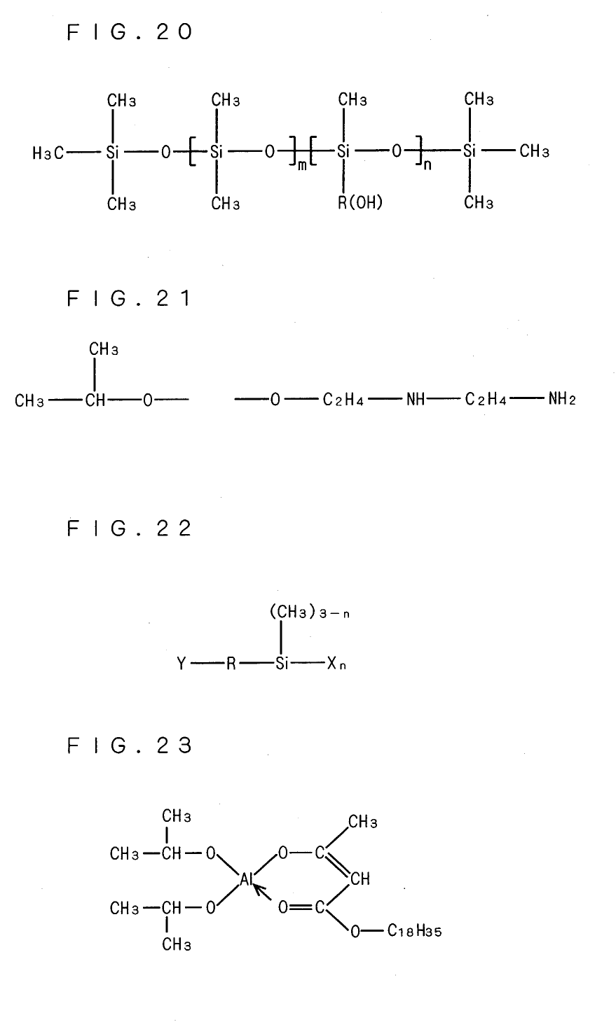

The silicon wafer W on which the resist surface treatment agent membrane 2 is deposited is subjected to mixing bake at 80 to 200° C. for 30 to 120 seconds (preferably at 120° C. for 90 seconds) (FIG. 3F). With mixing bake, the boundary region B selectively provided with the reactivity reacts with the resist surface treatment agent membrane 2. That is, S—co-tBCA contained in the boundary region B that is partly deprotected reacts with the organically modified silicone oil contained in the resist surface treatment agent membrane 2. An exemplary product by this reaction is shown in FIG. 18. At the same time, the reaction between the N-methoxymethylethyleneurea compound and organically modified silicone oil contained in the resist surface treatment agent membrane 2 also progresses.

With the progress of these reactions, the resist reinforced portion R is formed on the boundary region B. The resist reinforced portion R, containing Si in molecules, has an etching rate at the time of dry etching significantly lower than that of other portions. Therefore, the resist reinforced portion R functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the silicon wafer W after mixing bake, the unreacted portion 2a of the resist surface treatment agent membrane 2 is developed and removed by the same developing solution (pure water) described in the first preferred embodiment, following which drying is conducted at 110° C. for 60 seconds (FIG. 3G).

Next, plasma dry development is performed using the resist reinforced portion R and unexposed portion 3a as a mask (FIG. 3H). With plasma dry development, the resin film 4 is removed leaving lower layers of the resist reinforced portion R and unexposed portion 3a. Thereafter, a thin film is dry etched using the resist pattern formed as described above as a mask.

In the fine pattern forming method according to the present embodiment, the deposited resist surface treatment agent membrane 2 is used as a silylation agent membrane, as in the first and second preferred embodiments. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved. Still further, a wiring width w2 of the fine pattern can be made wider than a mask pattern and an isolation width w1 of the resist pattern can be made narrower than the mask pattern, allowing the pattern size to be controlled to exceed the wavelength limit of the light source. In addition, the degree that silylation progresses in the silylated layer does not vary in the depth direction, allowing an excellent resist pattern to be obtained in a shape that rises vertically on the silicon wafer W.

Fourth Preferred Embodiment

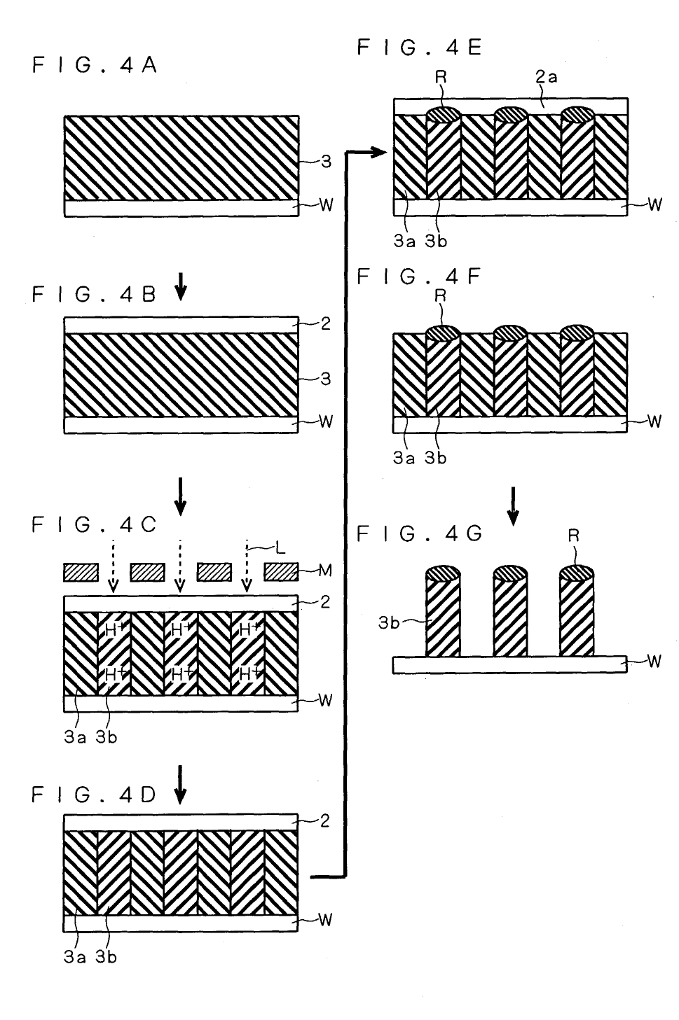

A fine pattern forming method according to the fourth preferred embodiment will be described referring to sectional views shown in FIGS. 4A through 4G illustrating the flow of steps. The same components described in the first to third preferred embodiments are assigned the same reference characters in the following description, detailed explanation of which is thus omitted.

The same resist film 3 described in the third preferred embodiment is deposited on the silicon wafer W using a spinner (FIG. 4A).

The silicon wafer W on which the resist film 3 is deposited is subjected to prebake at 110° C. for 70 seconds. Prebake causes propyleneglycolmonoethylacetate contained in the resist film 3 to volatilize, making the resist film 3 dense in a film thickness of 0.5 μm.

On the silicon wafer W after prebake, the same resist surface treatment agent membrane 2 described in the first preferred embodiment is deposited on the resist film 3 using a spinner (FIG. 4B).

The silicon wafer W after the resist surface treatment agent membrane 2 is deposited thereon is radiated with light L from an exposure light source through the exposure mask M having a predetermined pattern shape, whereby selective exposure is conducted (FIG. 4C). A KrF excimer-laser stepper is used for exposure. Exposure causes triphenylsulfonium trifluoromethylsulfonate to decompose, whereby a proton H⁺ is generated.

The silicon wafer W as exposed is subjected to post-exposure bake at 80 to 200° C. for 30 to 120 seconds (preferably at 120° C. for 70 seconds) (FIG. 4D). With post-exposure bake, the t-butyl group of S—co-tBCA contained in the exposed portion 3b is eliminated in the presence of an acid catalyst, whereby S—co-tBCA is deprotected. Therefore, post-exposure bake causes the exposed portion 3b to have the reactivity with the resist surface treatment agent membrane 2.

On the other hand, S—co-tBCA of the unexposed portion 3a remains protected by the t-butyl group even after post-exposure bake. Therefore, the unexposed portion 3a has no reactivity with the resist surface treatment agent membrane 2 even after post-exposure bake.

That is, post-exposure bake selectively provides the exposed portion 3b with the reactivity with the resist surface treatment agent membrane 2.

The silicon wafer W after post-exposure bake is subjected to mixing bake at 80 to 200° C. for 30 to 120 seconds (preferably at 120° C. for 90 seconds) (FIG. 4E). With mixing bake, the top surface of the exposed portion 3b selectively provided with the reactivity reacts with the resist surface treatment agent membrane 2. That is, deprotected S—co-tBCA contained in the exposed portion 3b reacts with the organically modified silicone oil contained in the resist surface treatment agent membrane 2. At the same time, the reaction between the N-methoxymethylethyleneurea compound and organically modified silicone oil contained in the resist surface treatment agent membrane 2 also progresses.

With the progress of these reactions, the resist reinforced portion R that is not removed in the step of developing the resist surface treatment agent to be described later is formed on the top surface of the exposed portion 3b. The resist reinforced portion R, containing Si in molecules, has an etching rate at dry etching significantly lower than that of other portions. Therefore, the resist reinforced portion R functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the other hand, the reaction between the organically modified silicone oil contained in the resist surface treatment agent membrane 2 and S—co-tBCA contained in the unexposed portion 3a does not progress. Thus, the unreacted portion 2a of the resist surface treatment agent membrane 2 on the unexposed portion 3a is removed in the subsequent step of developing the resist surface treatment agent.

On the silicon wafer W after mixing bake, the unreacted portion 2a of the resist surface treatment agent membrane 2 is developed and removed by a developing solution, following which drying is conducted at 110° C. for 60 seconds (FIG. 4F). In the present embodiment, pure water as a solvent of the resist surface treatment agent is used for a developing solution that only dissolves the unreacted portion 2a and does not dissolve other portions than the unreacted portion 2a.

Next, plasma dry development is performed using the resist reinforced portion R as a mask (FIG. 4G). With plasma dry development, the resist film 3 is removed leaving a lower layer of the resist reinforced portion R of the resist film 3.

In the fine pattern forming method according to the present embodiment, the deposited resist surface treatment agent membrane 2 is used as a silylation agent membrane. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved.

Fifth Preferred Embodiment

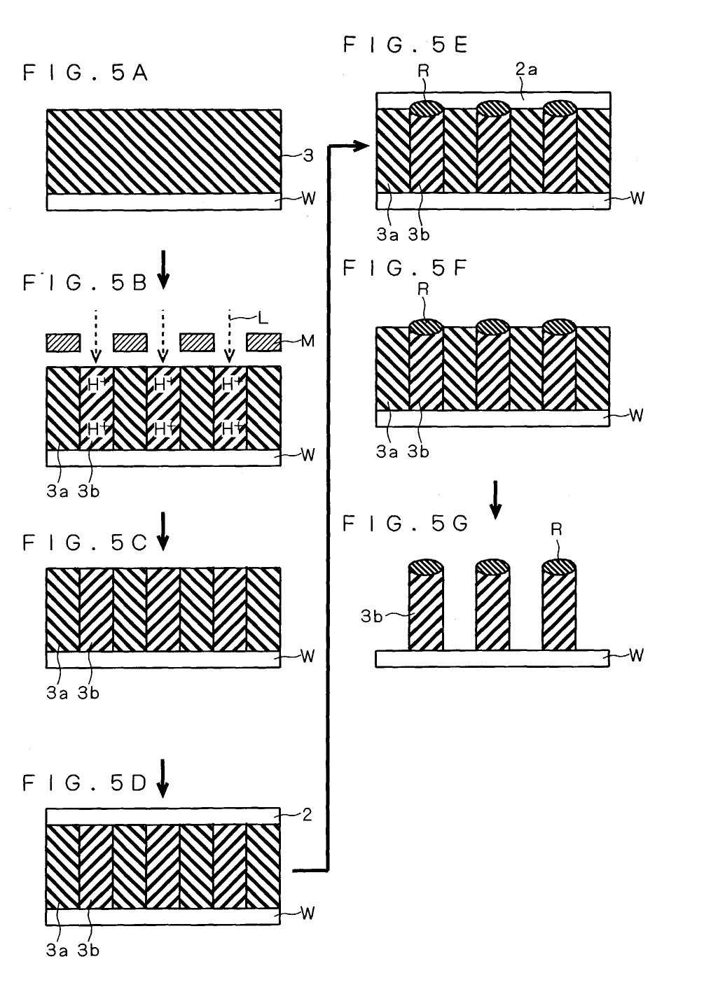

A fine pattern forming method according to the fifth preferred embodiment will be described referring to sectional views shown in FIGS. 5A through 5G illustrating the flow of steps. The same components described in the first to fourth preferred embodiments are assigned the same reference characters in the following description, detailed explanation of which is thus omitted.

The same resist film 3 described in the third preferred embodiment is deposited on the silicon wafer W using a spinner (FIG. 5A).

The silicon wafer W on which the resist film 3 is deposited is subjected to prebake at 110° C. for 70 seconds. Prebake causes propyleneglycolmonoethylacetate contained in the resist film 3 to volatilize, making the resist film 3 dense in a film thickness of 0.5 μm.

The silicon wafer W after prebake is radiated with light L from an exposure light source through the exposure mask M having a predetermined pattern shape, whereby selective exposure is conducted (FIG. 5B). A KrF excimer-laser stepper is used for exposure. Exposure causes triphenylsulfonium trifluoromethylsulfonate to decompose in the exposed portion 3b, whereby a proton H⁺ is generated.

The silicon wafer W as exposed is subjected to post-exposure bake at 80 to 200° C. for 30 to 120 seconds (preferably at 120° C. for 70 seconds) (FIG. 5C). With post-exposure bake, the t-butyl group of S—co-tBCA contained in the exposed portion 3b is eliminated in the presence of an acid catalyst, whereby S—co-tBCA is deprotected. Therefore, post-exposure bake causes the exposed portion 3b to have the reactivity with the resist surface treatment agent membrane 2 to be formed later.

On the other hand, S—co-tBCA of the unexposed portion 3a remains protected by the t-butyl group even after post-exposure bake. Therefore, the unexposed portion 3a has no reactivity with the resist surface treatment agent membrane 2 even after post-exposure bake.

That is, post-exposure bake selectively provides the exposed portion 3b with the reactivity with the resist surface treatment agent membrane 2.

On the silicon wafer W after post-exposure bake, the same resist surface treatment agent membrane 2 described in the first preferred embodiment is deposited on the resist film 3 using a spinner (FIG. 5D).

The silicon wafer W on which the resist surface treatment agent membrane 2 is deposited is subjected to mixing bake at 80 to 200° C. for 30 to 120 seconds (preferably at 120° C. for 90 seconds) (FIG. 5E). With mixing bake, the top surface of the exposed portion 3b selectively provided with the reactivity reacts with the resist surface treatment agent membrane 2. That is, deprotected S—co-tBCA contained in the exposed portion 3b reacts with the organically modified silicone oil contained in the resist surface treatment agent membrane 2. At the same time, the reaction between the N-methoxymethylethyleneurea compound and organically modified silicone oil contained in the resist surface treatment agent membrane 2 also progresses.

With the progress of these reactions, the resist reinforced portion R that is not removed in the step of developing the resist surface treatment agent to be described later is formed on the top surface of the exposed portion 3b. The resist reinforced portion R, containing Si in molecules, has an etching rate at the time of dry etching significantly lower than that of other portions. Therefore, the resist reinforced portion R functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the other hand, the reaction between the organically modified silicone oil contained in the resist surface treatment agent membrane 2 and S—co-tBCA contained in the unexposed portion 3a does not progress. Thus, the unreacted portion 2a of the resist surface treatment agent membrane 2 on the unexposed portion 3a is removed in the subsequent step of developing the resist surface treatment agent.

On the silicon wafer W after mixing bake, the unreacted portion 2a of the resist surface treatment agent membrane 2 is developed and removed by the same developing solution (pure water) described in the first preferred embodiment, following which drying is conducted at 110° C. for 60 seconds (FIG. 5F).

Next, plasma dry development is performed using the resist reinforced portion R as a mask (FIG. 5G). With plasma dry development, the unexposed portion 3a of the resist film 3 is removed leaving the exposed portion 3b corresponding to a lower layer of the resist reinforced portion R.

In the fine pattern forming method according to the present embodiment, the deposited resist surface treatment agent membrane 2 is used as a silylation agent membrane as in the first to fourth preferred embodiments. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved.

Sixth Preferred Embodiment

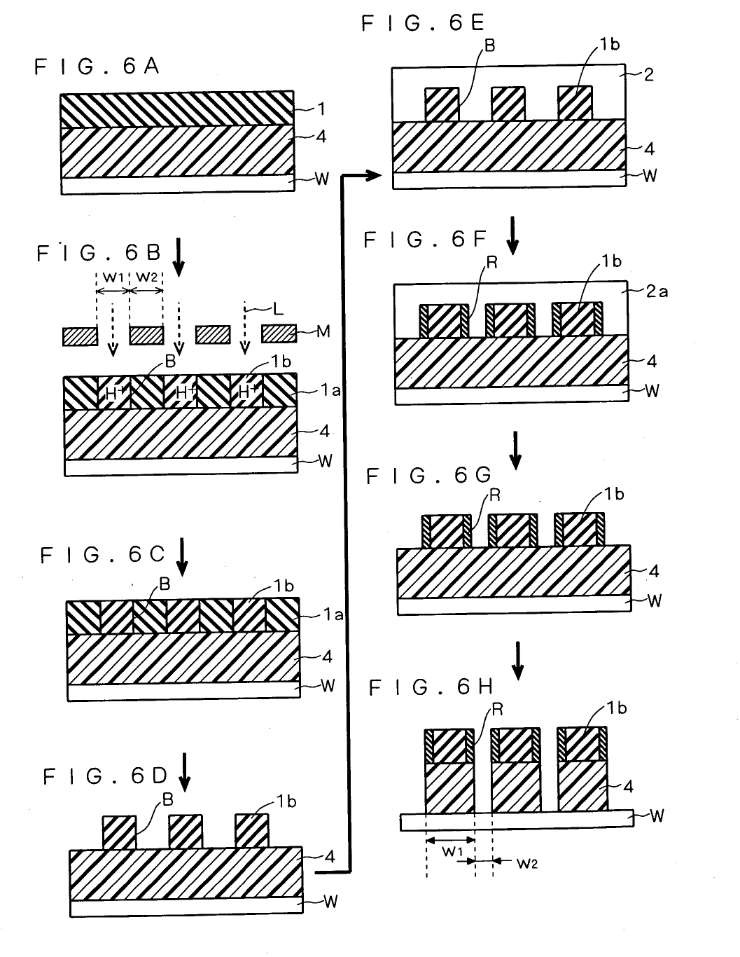

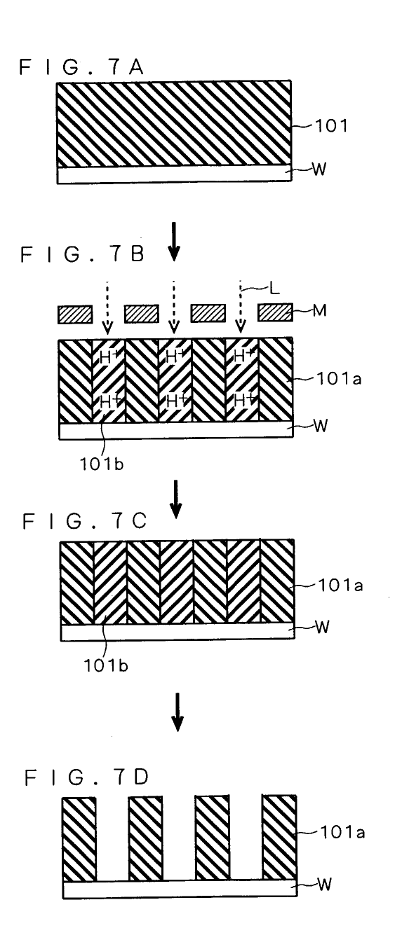

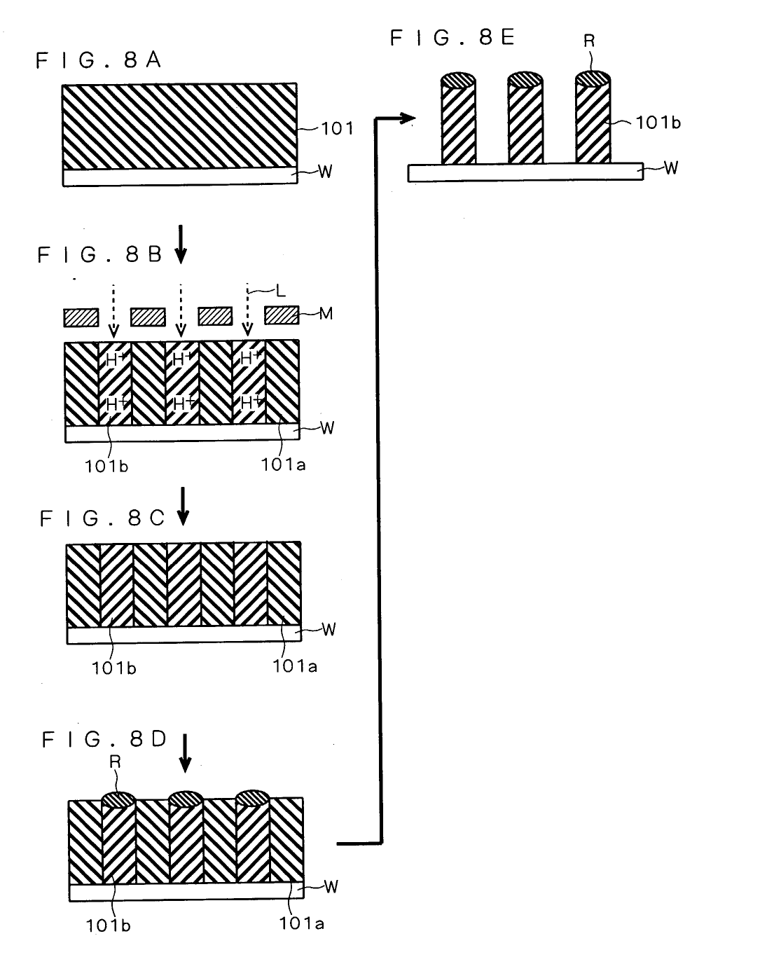

A fine pattern forming method according to the sixth preferred embodiment will be described referring to sectional views shown in FIGS. 6A through 6H illustrating the flow of steps. The same components described in the first to fifth preferred embodiments are assigned the same reference characters in the following description, detailed explanation of which is thus omitted.

The same resin film 4 described in the third preferred embodiment is deposited on the silicon wafer W using a spinner (FIG. 6A).

On the silicon wafer W on which the resin film 4 is deposited, the same resist film 1 described in the first preferred embodiment is deposited using a spinner.

The silicon wafer W on which the resist film 1 is deposited is subjected to prebake at 110° C. for 70 seconds. Prebake causes propyleneglycolmonoethylacetate contained in the resist film 1 to volatilize, making the resist film 1 dense in a film thickness of 0.5 μm.

The silicon wafer W after prebake is radiated with light L from an exposure light source through the exposure mask M having a predetermined pattern shape, whereby selective exposure is conducted (FIG. 6B). A KrF excimer-laser stepper is used for exposure. Exposure causes triphenylsulfonium trifluoromethylsulfonate to decompose in the exposed portion 1b, whereby a proton H⁺ is generated.

The silicon wafer W as exposed is subjected to post-exposure bake at 80 to 200° C. for 30 to 120 seconds (preferably at 120° C. for 70 seconds) (FIG. 6C). With post-exposure bake, S—co—HS contained in the exposed portion 1b produces a crosslinking reaction in the presence of an acid catalyst, whereby phenolic hydroxyl group as a reactive functional group is protected (i.e., the reactivity is lost). Therefore, post-exposure bake causes the exposed portion 1b to be alkali-insoluble, so that the reactivity with the resist surface treatment agent membrane 2 to be formed later is lost.

On the other hand, in the unexposed portion 1a except the boundary region B with respect to the exposed portion 1b, the phenolic hydroxyl group as reactive functional group of S—co—HS maintains the reactivity even after post-exposure bake. Thus, the unexposed portion 1a is alkali-soluble and maintains the reactivity with the resist surface treatment agent membrane 2 even after post-exposure bake.

Further, S—co—HS contained in the resin film 4 produces a crosslinking reaction at post-exposure bake in the presence of an acid catalyst, whereby the phenolic hydroxyl group as the reactive functional group is protected (i.e., the reactivity is lost). Therefore, post-exposure bake causes the resin film 4 to be alkali-insoluble, so that the reactivity with the resist surface treatment agent membrane 2 is lost.

The boundary region B of the unexposed portion 1a with respect to the exposed portion 1b, where protection of S—co—HS partly progresses, is thus not completely alkali-soluble, but is provided with reactivity with the resist surface treatment agent membrane 2.

That is, post-exposure bake selectively provides the unexposed portion 1a (including the boundary region B) with the reactivity with the resist surface treatment agent membrane 2. However, the unexposed portion 1a except the boundary region B is removed in the developing step to be described later, which substantially means that the reactivity with the resist surface treatment agent membrane 2 is selectively provided only for the boundary region B.

The silicon wafer W after post-exposure bake is subjected to a developing process for 1 minute with 2.38 wt % aqueous solution of tetramethylammoniumhydroxide (TMAH) as an alkali developing solution. With this developing process, the unexposed portion 1a in an alkali-soluble state is removed (FIG. 6D). The silicon wafer W after the developing process is dried at 110° C. for 60 seconds.

On the silicon wafer W as dried, the same resist surface treatment agent membrane 2 described in the first preferred embodiment is deposited using a spinner. Here, the resist surface treatment agent membrane 2 is deposited in such a film thickness that the exposed portion 1b remaining in an alkali-insoluble state and the boundary region B are completely covered (FIG. 6E).

The silicon wafer W on which the resist surface treatment agent membrane 2 is deposited is subjected to mixing bake at 80 to 200° C. for 30 to 120 seconds (preferably at 120° C. for 90 seconds) (FIG. 6F). With mixing bake, the boundary region B selectively provided with the reactivity reacts with the resist surface treatment agent membrane 2. That is, S—co—HS contained in the boundary region B that is partly protected reacts with the organically modified silicone oil contained in the resist surface treatment agent membrane 2. At the same time, the reaction between the N-methoxymethylethyleneurea compound and organically modified silicone oil contained in the resist surface treatment agent membrane 2 also progresses.

With the progress of these reactions, the resist reinforced portion R is formed on the boundary region B. The resist reinforced portion R, containing Si in molecules, has an etching rate at the time of dry etching significantly lower than that of other portions. Therefore, the resist reinforced portion R functions as a mask layer having dry etch resistance.

The progress of these reactions varies depending on the mixing ratio of the organically modified silicone oil and N-methoxymethylethyleneurea compound as well as the functional group equivalent weight of the organically modified silicone oil. Thus, it is desirable to experimentally determine in advance the amount of the organically modified silicone oil and N-methoxymethylethyleneurea compound as well as the functional group equivalent weight of the organically modified silicone oil such that a predetermined degree of pattern resolution can be obtained.

On the silicon wafer W after mixing bake, the unreacted portion 2a of the resist surface treatment agent membrane 2 is developed and removed by the same developing solution (pure water) described in the first preferred embodiment, following which drying is conducted at 110° C. for 60 seconds (FIG. 6G).

Next, plasma dry development is performed using the resist reinforced portion R and exposed portion 1b as a mask (FIG. 6H). With plasma dry development, the resin film 4 is removed leaving lower layers of the resist reinforced portion R and exposed portion 1b.

In the fine pattern forming method according to the present embodiment, the deposited resist surface treatment agent membrane 2 is used as a silylation agent membrane, as in the first to fifth preferred embodiments. This improves the process stability as compared to the case of using a gaseous or liquid silylation agent, as well as facilitating handling of materials. Further, the use of chemically amplified resist allows appropriate exposure even if light from the exposure light source is weakened by shortening the wavelength. Furthermore, the resist surface treatment agent contains a crosslinking compound that reacts with a dry etch resistive compound, whereby pattern resolution can be improved. Still further, the wiring width w1 of the fine pattern can be made wider than a mask pattern and the isolation width w2 of the fine pattern can be made narrower than the mask pattern, allowing the pattern size to be controlled to exceed the wavelength limit of the light source. In addition, the degree that silylation progresses in the silylated layer does not vary in the depth direction, allowing an excellent resist pattern to be obtained in a shape that rises vertically on the silicon wafer W.

Variants

<Resist surface treatment agent>

In the aforementioned first to sixth preferred embodiments, a compound obtained by stirring a water-soluble organically modified silicone oil containing a polyether group, an N-methoxymethylethyleneurea compound and pure water has been used as a resist surface treatment agent, however, the resist surface treatment agent is not limited thereto. Specifically, the same results are obtained by using the following resist surface treatment agents.

A resist surface treatment agent obtained by stirring and mixing the following (D) to (G) at room temperature for 2 hours:

(D) 80g of water-soluble organically modified silicone oil (KF354L, Shin-Etsu Chemical Co., Ltd.) containing a polyether group as a Si-containing dry etch resistive compound;

(E) 20g of N-methoxymethylethyleneurea compound as a crosslinking compound;

(F) 50g of 10 wt % solution of polyvinylacetal resin (Sekisui Chemical Co., Ltd., Minato-ku, Tokyo, Japan) as a crosslinking compound; and

(G) 800g of pure water as a solvent An exemplary chemical formula of polyvinylacetal resin is shown in FIG. 19.

A resist surface treatment agent obtained by stirring and mixing the following (H) to (J) at room temperature for 2 hours:

(H) 50g of organically modified silicone oil (X22-4015, Shin-Etsu Chemical Co., Ltd.) containing a carbinol group as a Si-containing dry etch resistive compound;

(I) 20g of N-methoxymethylethyleneurea compound as a crosslinking compound;

(J) 800g of cyclohexanol as a solvent

An exemplary chemical formula of the organically modified silicone oil containing a carbinol group is shown in FIG. 20.

A resist surface treatment agent obtained by stirring and mixing the following (K) to (M) at room temperature for 2 hours:

(K) a titanate coupling agent (KR44, Ajinomoto Fine-Techno CO., Inc, Kawasaki-ku, Kawasaki-shi, Japan) as a Ti containing dry etch resistive compound;

(L) 50g of 10 wt % solution of polyvinylacetal resin (Sekisui Chemical Co., Ltd.) as a crosslinking compound; and

(M) 800g of pure water as a solvent A functional group contained in the titanate coupling agent is shown in FIG. 21.

The dry etch resistive compound contained in the resist surface treatment agent is not limited to those described above. A compound that contains, in molecules, an element such as Si, Ti or Al and a functional group having reactivity with an exposed portion or an unexposed portion selectively provided with reactivity and that is soluble or dispersible in a slurry state in a solvent that is not completely mixed with a resist film (the solvent differs depending on the resist).

More specifically, a silicone oil can be used that has been subjected to modification of the reactive functional group such as amino modification, polyether modification, epoxy modification, carbinol modification, mercapto modification, methacryl modification, phenol modification, amino/polyether modification or epoxy/polyether modification. Further, a siloxane compound of low molecular weight containing one or two siloxane bonds may be used instead of a silicone oil that contains a large number of siloxane bonds (polysiloxane).

Alternatively, silane that contains a reactive functional group in molecules may be used. For instance, in the chemical formula shown in FIG. 22, a silane coupling agent may be used whose functional group X is selected from the group consisting of chloro group, alkoxy group, acetoxy group, isopropenoxy group and amino group, and whose functional group Y is selected from the group consisting of vinyl group, epoxy group, methacryl group, amino group, mercapto group, styryl group, acryloxy group, ureido group, chloropropyl group, sulfide group, isocyanate group and alkoxy group. More specifically, the following may be used: vinyltrichlorosilane; vinyltrimethoxysilane; vinyltriethoxysilane; 2-(3,4 epoxycyclohexyl)-ethyltrimethoxysilane; 3-glycidoxypropyltrimethoxysilane; 3-glycidoxypropylmethyldiethoxysilane; 3-glycidoxypropyltriethoxysilane; p-styryltrimethoxysilane; 3-methacryloxypropylmethyldimethoxysilane; 3-methacryloxypropyltrimethoxysilane; 3-methacryloxypropylmethyldiethoxysilane; 3-methacryloxypropyltriethoxysilane; 3-acryloxypropyltrimethoxysilane; (aminoethyl)3-aminopropylmethyldimethoxysilane; N-2(aminoethyl) 3-aminopropyltrimethoxysilane; N-2 (aminoethyl)3-aminopropyltriethoxysilane; 3-aminopropyltrimethoxysilane; 3-aminopropyltriethoxysilane; 3-triethoxysilyl-N-(1,3-dimethyl-butyliden) propylamine; N-phenyl-3-aminopropyltrimethoxysilane; N-(vinylbenzyl)-2-aminoethyl-3-aminopropyltrimethoxysilane; 3-ureidopropyltriethoxysilane; 3-chloropropyltrimethoxysilane; 3-mercaptopropylmethyldimethoxysilane; 3-mercaptopropyltrimethoxysilane; bis(triethoxysilylpropyl)tetrasulfide; and 3-isocyanatepropyltriethoxysilane.

Further, an aluminate coupling agent (AL-M, Ajinomoto Fine-Techno CO., Inc) may be used instead of a titanate coupling agent. The chemical formula of the aluminate coupling agent is shown in FIG. 23.

For the resist surface treatment agent, a solvent may be used that does not dissolve the resist film but can dissolve or disperse in a slurry state an etch resistive compound and a crosslinking compound. That is, water, an organic solvent that can be mixed with water, a polar solvent such as a compound of water and such organic solvent, or a nonpolar solvent such as benzen, toluene, cyclohexane, n-hexane, xylene, methylcyclohexane or cyclohexanol may be appropriately selected and used.

As described above, it is also desirable that the resist surface treatment agent contain a crosslinking substance such as polyethyleneimine, polyvinylacetal, melamine derivatives or urea derivatives. Adjusting the amount of addition of such crosslinking substance allows a predetermined degree of resolution to be obtained.

Further, the resist surface treatment agent may contain weak acid, weak base or dispersing agent so as to improve the solution stability. The weak acid is, for example, carboxylic acid such as oxalic acid. The weak base is, for example, ammonium hydroxide, primary amine such as ethanolamine, secondary amine, or tertiary amine. Further, the resist surface treatment agent may contain water soluble resin such as polyvinylalcohol, polyvinylpyrrolidone, polyethyleneoxide, polyacrylate, polyethyleneglycol, polyvinylether, polyacrylamide, polyethyleneimine, copolymer of stylene and maleic anhydride, polyvinylamine, alkyd resin, or sulfonamide.

<Resist>

Resin contained in the resist used in the first and second preferred embodiments (positive type) and the sixth preferred embodiment (negative type) is only required to produce a crosslinking reaction in the presence of a hydrogen ion catalyst. For instance, a novolak resin may be used instead of S—co—HS. As a crosslinking agent, 2,6-dihydroxymethyl-4-t-butyl-hydroxybenzene or the like may be used.

In the third preferred embodiment (positive type) and the fourth and fifth preferred embodiments (negative type), the resist surface treatment agent as used contains a dry etch resistive compound containing a reactive polyether group and the resist as selected contains resin in which the carboxyl group having reactivity with the polyether group is protected (esterified) by the t-butyl group, however, the resin contained in the resist is not necessarily limited thereto. That is, the resin is only required to have a structure in which a functional group having reactivity with the resist surface treatment agent is protected by a blocking group and such protection is lost by catalysis of acid generated by exposure.

For instance, resin may also be used that has a structure in which a phenolic hydroxyl group is protected by a blocking group and such protection is lost by catalysis of acid generated by exposure. More specifically, poly (p-butoxycarbonyloxystyrene) obtained by esterifying (protecting) polyhydroxystyrene with t-butoxycarboxylic acid may also be used.

Another type of resist that can be used in the third preferred embodiment (positive type) and the fourth and fifth preferred embodiments (negative type) is one that produces a crosslinking reaction in the unexposed portion 3a with heat treatment but not in the exposed portion 3b. For instance, resist containing a novolak resin and naphthoquinonediazide may also be used. Such resist loses the ability of diazo coupling in the exposed portion 3b since naphthoquinonediazide decomposes into carboxylic acid. This hinders a crosslinking reaction by heat in the exposed portion 3b. The reactivity with the organically modified silicone oil in the unexposed portion 3a where a crosslinking reaction progresses is reduced as compared to the exposed portion 3b where a crosslinking reaction is hindered, whereby only the exposed portion 3b selectively reacts with the resist surface treatment agent membrane 2 at mixing bake, so that the resist reinforced portion R is formed.

Further, the resist may contain a light absorber such as a dye. The resist containing such light absorber can prevent the occurrence of a standing wave therein at exposure due to reflected light from the substrate, allowing the concentration of hydrogen ions in an exposed region to be further uniformalized.

<Others>

The photo acid generator is not limited to triphenylsulfonium trifluoromethylsulfonate, but may be a substance that photochemically produces an acid catalyst with light having a wavelength of a light source as used. A photo acid generator based on phenyldiazonium salt, diphenyliodonium salt, halogen or the like instead of triphenylsulfonium salt may be used.

Further, although the first through sixth preferred embodiments have described that exposure is performed using the KrF excimer-laser stepper, “exposure” mentioned in the present invention involves one that is performed using another light source having different wavelength. Radiation by electron beams or X-rays is also involved.

While the invention has been shown and described in detail, the foregoing description is in all aspects illustrative and not restrictive. It is therefore understood that numerous modifications and variations can be devised without departing from the scope of the invention.

What is claimed is:

1. A method for forming a fine pattern on a substrate, comprising the steps of:
(a) depositing a photoresist film on said substrate;
(b) depositing a resist surface treatment agent membrane having dry etch resistance on said photoresist film;
(c) selectively exposing said photoresist film, thereby forming an exposed portion and an unexposed portion on said photoresist film;
(d) providing one of said exposed portion and said unexposed portion with selective reactivity with said resist surface treatment agent membrane;
(e) selectively causing said photoresist film and said resist surface treatment agent membrane to react with each other, thereby forming a mask layer having dry etch resistance;
(f) removing an unreacted portion of said resist surface treatment agent membrane; and
(g) performing dry development using said mask layer as a mask.

2. The method according to claim 1, wherein said step (b) is performed before said step (c).

3. The method according to claim 1, wherein said step (b) is performed after said step (c).

4. A method for forming a fine pattern on a substrate, comprising the steps of:
(a) forming a resin film on said substrate;
(b) depositing a photoresist film on said resin film;
(c) selectively exposing said photoresist film, thereby forming an exposed portion and an unexposed portion on said photoresist film;
(d) providing a boundary of one of said exposed portion and said unexposed portion with selective reactivity with a resist surface treatment agent membrane having dry etch resistance;
(e) removing the other of said exposed portion and said unexposed portion;
(f) depositing said resist surface treatment agent membrane on said one of said exposed portion and said unexposed portion and on an uncoated surface of said resin film;
(g) selectively causing said one of said exposed portion and said unexposed portion to react with said resist surface treatment agent membrane, thereby forming a mask layer having dry etch resistance;
(h) removing an unreacted portion of said resist surface treatment agent membrane; and
(i) performing dry development of said resin film using said mask layer as a mask.

5. The method according to claim 1, wherein said photoresist film is made of a chemically amplified resist.

6. A resist surface treatment agent being selectively caused to react with one of an exposed portion and an unexposed portion of a resist film for use in forming a fine pattern on a substrate, thereby forming a mask layer having dry etch resistance, said resist surface treatment agent containing:
a dry etch resistive compound having selective reactivity with said one of said exposed portion and said unexposed portion; and
a solvent that does not dissolve said resist film obtained by depositing resist on said substrate.

7. The resist surface treatment agent according to claim 6, wherein said dry etch resistive compound contains in molecules at least one kind of element selected from the group consisting of Si, Ti and Al.

8. The resist surface treatment agent according to claim 7, wherein said dry etch resistive compound is one of organically modified siloxane and organically modified silane.

9. The resist surface treatment agent according to claim 8, wherein said dry etch resistive compound is organically modified silicone oil.

10. The resist surface treatment agent according to claim 9, wherein said organically modified silicone oil is at least one kind of compound selected from the group consisting of: amino modified silicone oil; polyether modified silicone oil; epoxy modified silicone oil; carbinol modified silicone oil; mercapto modified silicone oil; methacryl modified silicone oil; phenol modified silicone oil; amino/polyether modified silicone oil; and epoxy/polyether modified silicone oil.

11. The resist surface treatment agent according to claim 7, wherein said dry etch resistive compound is one of a titanate coupling agent and an aluminate coupling agent.

12. The resist surface treatment agent according to claim 6, further containing a crosslinking compound having reactivity with said dry etch resistive compound.

13. The resist surface treatment agent according to claim 12, wherein said crosslinking compound is one of polyethyleneimine, polyvinylacetal, melamine derivatives and urea derivatives.

14. The resist surface treatment agent according to claim 6, being coated on said resist film to form a membrane.

15. The method according to claim 1, wherein said substrate is a semiconductor substrate.

16. The method according to claim 4, wherein said substrate is a semiconductor substrate.
